(19) United States
(12) Patent Application Publication
(10) Pub. No.: US 2025/0185267 A1
(43) Pub. Date: Jun. 5, 2025

(54) SEMICONDUCTOR DEVICE

(71) Applicant: FUJI ELECTRIC CO., LTD., Kanagawa (JP)

(72) Inventors: Kazuki KAMIMURA, Matsumoto-city (JP); Tatsuya NAITO, Matsumoto-city (JP)

(21) Appl. No.: 19/042,028

(22) Filed: Jan. 31, 2025

Related U.S. Application Data
(63) Continuation of application No. PCT/JP2023/039249, filed on Oct. 31, 2023.

(30) Foreign Application Priority Data
Feb. 6, 2023 (JP) 2023-016375

(51) Int. Cl. H10D 12/00; H10D 62/10; H10D 84/80

(52) U.S. Cl. CPC H10D 12/481; H10D 62/102; H10D 62/127; H10D 84/811

(57) ABSTRACT

Provided is a semiconductor device including a semiconductor substrate, where the semiconductor substrate has: a transistor portion and a diode portion alternately arranged along a first direction, each having a longitudinal part in a second direction; and a current sensing unit arranged facing the transistor portion in the second direction, the transistor portion, the diode portion, and the current sensing unit each include: a drift region of a first conductivity type; and a base region of a second conductivity type provided between the drift region and an upper surface of the semiconductor substrate.

### BACKGROUND

### 1. Technical Field

The present invention relates to a semiconductor device.

### 2. Related Art

A semiconductor device including a current sensing unit has been known in the related art (see Patent Document 1 for example).

### PRIOR ART DOCUMENT

### Patent Document

Patent Document 1: Japanese Patent Application Publication No. 2021-192447

### BRIEF DESCRIPTION OF THE DRAWINGS

FIG. 1 illustrates an equivalent circuit of a semiconductor device 100 according to one embodiment of the present invention.

FIG. 2 illustrates a top view of one example of the semiconductor device 100 according to one embodiment of the present invention.

FIG. 3 illustrates an enlarged view of a region A in FIG. 2.

FIG. 4 illustrates one example of a cross section A-A′ in FIG. 3.

FIG. 5 illustrates one example of a cross section B-B′ in FIG. 3.

FIG. 6 illustrates one example of a cross section C-C′ in FIG. 2.

FIG. 7 illustrates top views of a mesa portion 60 of a transistor portion 70 and a mesa portion 63 of a current sensing unit 26.

FIG. 8 illustrates arrangement around the current sensing unit 26 of a measurement sample with a large chip size.

FIG. 9 illustrates arrangement around the current sensing unit 26 of a measurement sample with a small chip size.

FIG. 10 illustrates a result of measurement of dependency of a short circuit withstand time on active area.

FIG. 11 illustrates another example of the region A in FIG. 3.

FIG. 12 illustrates one example of a cross section A-B in FIG. 3.

FIG. 13 illustrates another example of the cross section B-B′ in FIG. 3.

FIG. 14 illustrates another example of an enlarged view of the region A in FIG. 2.

FIG. 15 illustrates one example of the cross section A-B in FIG. 14.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention. In the present specification, the same parts in each figure are denoted by the same signs and numerals, and the descriptions thereof may be omitted. In addition, for convenience of description, some configurations may not be illustrated.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a specific direction. For example, a Z axis direction is not limited to indicate the height direction with respect to the ground. It should be noted that a +Z axis direction and a −Z axis direction are directions opposite to each other. If the Z axis direction is described without describing the signs, it means that the direction is parallel to a +Z axis and a −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A case where a term such as “same” or “equal” is used in the present specification may include a case where an error due to a variation in manufacturing or the like is included. The error is, for example, within 10%.

In the present specification, a conductivity type of doping region doped with an impurity is described as a P type or an N type. In the present specification, the impurity may particularly mean either a donor of the N type or an acceptor of the P type, and may be described as a dopant.

In the present specification, doping means introducing the donor or the acceptor into the semiconductor substrate and turning it into a semiconductor presenting a conductivity type of the N type or a semiconductor presenting a conductivity type of the P type. In the present specification, the doping concentration in the N type region may be referred to as the donor concentration, and the doping concentration in the P type region may be referred to as the acceptor concentration.

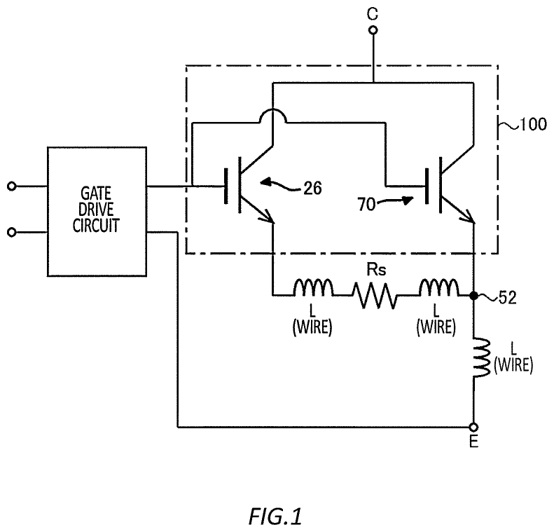

FIG. 1 illustrates an equivalent circuit of a semiconductor device 100 according to one embodiment of the present invention. The semiconductor device 100 includes a transistor portion 70 and a current sensing unit 26. The current sensing unit 26 has a structure similar to that of the transistor portion 70, and measures a current flowing through the transistor portion 70. The transistor portion 70 and the current sensing unit 26 may be IGBTs.

A collector electrode of the transistor portion 70 and a collector electrode of the current sensing unit 26 are connected to each other, and are connected to a common collector terminal (C). A gate conductive portion of the transistor portion 70 and a gate conductive portion of the current sensing unit 26 are connected to a common gate drive circuit. On the other hand, an emitter electrode 52 of the transistor portion 70 and a sense emitter electrode of the current sensing unit 26 are electrically separated inside the semiconductor device 100. The emitter electrode 52 of the transistor portion 70 is connected to an emitter terminal (E), and is supplied with an emitter potential. The sense emitter electrode of the current sensing unit 26 is also connected to the emitter terminal, but is supplied with an emitter potential via a sense resistor Rs branched from the emitter electrode 52.

A predetermined current flows through the transistor portion 70 if the semiconductor device 100 operates, and a current corresponding to a current value of the transistor portion 70 flows through the current sensing unit 26. A value of current flowing through the current sensing unit 26 is measured from a voltage drop across the sense resistor Rs at that time. The current value of the transistor portion 70 is estimated based on a result of measurement by the current sensing unit 26. This makes it possible to detect an overcurrent in the transistor portion 70 and to stop the device. It should be noted that L represents an inductance component of a wire.

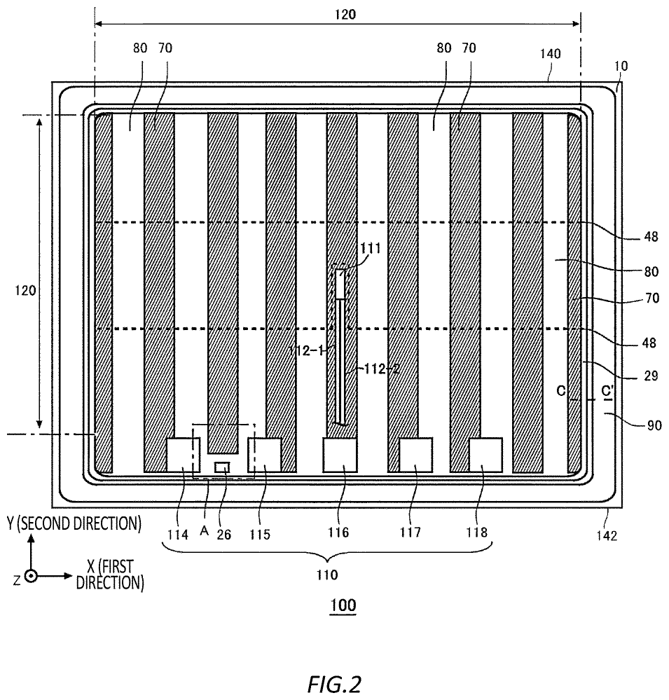

FIG. 2 illustrates a top view of one example of the semiconductor device 100 according to one embodiment of the present invention. FIG. 2 shows a position obtained by projecting a position of each member onto an upper surface of a semiconductor substrate 10. In FIG. 2, only some members of the semiconductor device 100 are shown, and some members thereof are omitted.

The semiconductor device 100 includes the semiconductor substrate 10. The semiconductor substrate 10 is a substrate formed of a semiconductor material. The semiconductor substrate 10 is, for example, a silicon substrate. In the present specification, an end portion of an outer periphery of the semiconductor substrate 10 in a top view is referred to as an outer peripheral end 140. The top view refers to a view seen from an upper surface side of the semiconductor substrate 10 in a direction parallel to a Z axis. In addition, any end side of the outer peripheral end 140 of the semiconductor substrate 10 in a top view is referred to as a first end side 142. In a top view, a direction parallel to the first end side 142 is referred to as an X axis direction, and a direction perpendicular to the first end side 142 is referred to as a Y axis direction.

The semiconductor substrate 10 is provided with an active portion 120. The active portion 120 is a region through which a main current flows in a depth direction between the upper surface and a lower surface of the semiconductor substrate 10 if the semiconductor device 100 operates. The emitter electrode 52 is provided above the active portion 120, but is omitted in FIG. 2.

The active portion 120 is provided with at least one of the transistor portion 70 including a transistor element such as an IGBT or a diode portion 80 including a diode element such as a free wheeling diode (FWD). In the example shown in FIG. 2, the transistor portion 70 and the diode portion 80 are alternately arranged along a first direction. In other words, the first direction is an array direction of the transistor portion 70 and the diode portion 80. The first direction may be an array direction of trench portions described later. In the present example, a transistor portion is provided at an end of the active portion in the first direction. In another example, the active portion 120 may be provided with only one of the transistor portion 70 or the diode portion 80.

The transistor portion 70 and the diode portion 80 may each have a longitudinal part in a second direction. In other words, the second direction is an extending direction of the transistor portion 70 and the diode portion 80. In the present specification, the first direction and the second direction will be respectively described as the X axis direction and the Y axis direction. A length of the transistor portion 70 in the Y axis direction is larger than a width of the transistor portion 70 in the X axis direction. Similarly, a length of the diode portion 80 in the Y axis direction is larger than a width of the diode portion 80 in the X axis direction. The extending direction of the transistor portion 70 and the diode portion 80 may be the same as a longitudinal direction of each trench portion described later.

The diode portions 80 includes a cathode region of an N+ type in a region in contact with the lower surface of the semiconductor substrate 10. In the present specification, a region provided with the cathode region is referred to as the diode portion 80. In other words, the diode portion 80 is a region overlapping with the cathode region in a top view. On the lower surface of the semiconductor substrate 10, a collector region of a P+ type may be provided in a region other than the cathode region. In the present specification, the diode portion 80 may also include a region extended from the diode portion 80 to an active well region 29 described later in the Y axis direction. The collector region is provided on a lower surface of the extended region.

The transistor portion 70 includes a collector region of the P+ type in a region in contact with the lower surface of the semiconductor substrate 10. In addition, the transistor portion 70 has: emitter regions of the N+ type: base regions of a P− type; and gate structures each including a gate conductive portion and a gate dielectric film, periodically arranged on the upper surface side of the semiconductor substrate 10.

A plurality of pad portions 110 (a current control pad 114, an auxiliary emitter pad 115, a gate pad 116, a cathode pad 117, and an anode pad 118 in the example shown in FIG. 2) are provided above the upper surface of the semiconductor substrate 10. The current control pad 114 is connected to the current sensing unit 26. The current sensing unit 26 has a same structure as that of the transistor portion 70, and has a smaller area (corresponding to area of a channel) than the transistor portion 70 in a top view. Detecting a current flowing through the current sensing unit 26 can estimate a current flowing through an entirety of the semiconductor device 100. When wiring an output from the current sensing unit 26 to the emitter electrode 52, a wiring may be extended from the current control pad 114. The auxiliary emitter pad 115 is connected to the emitter electrode 52 arranged above the upper surface of the semiconductor substrate 10. The wiring extended from the current control pad 114 may be connected to the emitter electrode 52 through wire bonding in the auxiliary emitter pad 115 such that a potential of the current control pad 114 is the same as that of the emitter electrode 52. The gate pad 116 is connected to a gate conductive portion of the transistor portion 70 and a gate conductive portion of the current sensing unit 26. The gate pad 116 in the present example is connected to each gate conductive portion via a gate runner described later. The cathode pad 117 and the anode pad 118 are connected to a temperature sense unit 111 described later. It should be noted that a number and types of pad portions 110 provided to the semiconductor substrate 10 are not limited to those in the example shown in FIG. 2.

Each pad portion is formed of a metal material such as aluminum. The plurality of pad portions 110 are arrayed in a predetermined direction between the active portion 120 and the first end side 142 at the upper surface of the semiconductor substrate 10. The plurality of pad portions 110 in the present example are arranged being sandwiched between the active portion 120 and the first end side 142 in the Y axis direction. The plurality of pad portions 110 in the present example are provided above the active well region 29 described later.

In an array direction of the plurality of pad portions 110, the current sensing unit 26 may be provided between any two pad portions of the pad portions 110. The current sensing unit 26 in the present example is arranged between two pad portions 110 in the first direction. The first direction in the present example is a same direction as the array direction of the pad portions 110.

The semiconductor device 100 includes a gate runner which transmits a gate voltage to the transistor portion 70. The semiconductor device 100 in the present example includes a first gate runner and a second gate runner 48 as gate runners. In the present example, each gate runner is provided above the upper surface of the semiconductor substrate 10, and is insulated from the upper surface of the semiconductor substrate 10 by an interlayer dielectric film.

In FIG. 2, the first gate runner is omitted. In a top view, the first gate runner is provided passing between the first end side 142 of the semiconductor substrate 10 and at least one of the pad portions 110. The first gate runner in the present example is provided passing between each of the current control pad 114, the auxiliary emitter pad 115, the gate pad 116, the cathode pad 117, and the anode pad 118, and the first end side 142, and parallel to the first end side 142. The first gate runner is connected to the gate pad 116.

In addition, the first gate runner is provided so as to enclose the active portion 120 between other end sides of the semiconductor substrate 10 and the active portion 120. In other words, the first gate runner in the present example is circularly provided along each end side of the semiconductor substrate 10. The first gate runner may be a metal wiring made of aluminum or the like, or may be a semiconductor wiring such as polysilicon doped with an impurity. The first gate runner may have a structure in which the metal wiring and the semiconductor wiring are provided overlapping with each other with a dielectric film in between. The dielectric film is provided with a contact hole for connecting the metal wiring and the semiconductor wiring.

The second gate runner 48 may be provided so as to cross the active portion 120. The second gate runner 48 may be a semiconductor wiring. The second gate runner 48 in the present example crosses the active portion 120 in the X axis direction. The second gate runner 48 is electrically connected to the first gate runner. The gate voltage is transmitted from the gate pad 116 to the transistor portion 70 and the current sensing unit 26 via the first gate runner and the second gate runner 48. Providing the second gate runner 48 in the active portion 120 can reduce variation in a length of wiring from the gate pad 116 in each region of the semiconductor substrate 10. The first gate runner or the second gate runner 48 may be provided around the pad portions 110 and between the active portion 120 and any of the pad portions 110.

The semiconductor substrate 10 includes the active well region 29. The active well region 29 encloses the transistor portion 70 and the diode portion 80 in a top view. The active well region 29 encloses the active portion 120 in a top view. The active well region 29 is a region of a second conductivity type having a higher doping concentration than the base region. The active well region 29 in the present example is of the P+ type. The active well region 29 may enclose the active portion 120 along the gate runner. The active well region 29 is also provided around the pad portions 110, but is omitted in FIG. 2.

An edge termination structure portion 90 is provided between the active well region 29 and the outer peripheral end 140 of the semiconductor substrate 10 at the upper surface of the semiconductor substrate 10. The edge termination structure portion 90 may be circularly arranged so as to enclose the active well region 29 at the upper surface of the semiconductor substrate 10. The edge termination structure portion 90 in the present example is arranged along the outer peripheral end 140 of the semiconductor substrate 10. The edge termination structure portion 90 reduces electric field strength on the upper surface side of the semiconductor substrate 10. The edge termination structure portion 90 has a structure of, for example, a guard ring, a field plate, a RESURF and a combination thereof.

A temperature sense wiring 112 is provided above the active portion 120. The temperature sense wiring 112 may be a semiconductor wiring. The temperature sense wiring 112 is connected to the temperature sense unit 111. The temperature sense wiring 112 extends to a region between the active portion 120 and the outer peripheral end 140 at the upper surface of the semiconductor substrate 10, and is connected to the cathode pad 117 and the anode pad 118. It should be noted that the semiconductor device 100 may not include the temperature sense unit 111 and the temperature sense wiring 112.

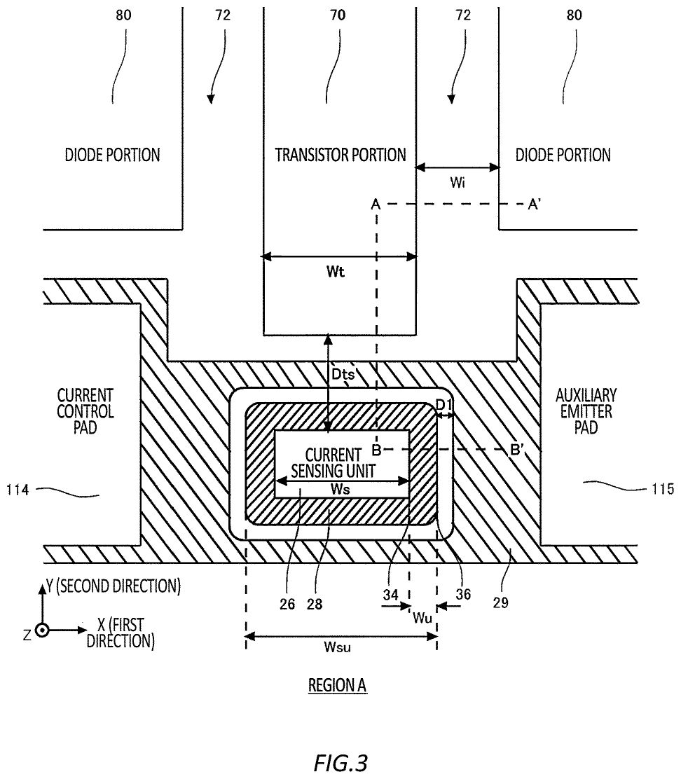

FIG. 3 illustrates an enlarged view of a region A in FIG. 2. The region A is a region around the current sensing unit 26. In a top view, the current sensing unit 26 is enclosed by a sense well region 28 of the second conductivity type. The sense well region 28 has a higher concentration than the base region, and is provided to a depth greater than that of the base region from the upper surface of the semiconductor substrate 10. The current sensing unit 26 in the present example is arranged facing the transistor portion 70 in the second direction.

The transistor portion 70 and the current sensing unit 26 facing each other makes it easier for holes to sneak from the transistor portion 70 into the current sensing unit 26. The holes which have sneaked into the current sensing unit 26 are accumulated in the current sensing unit 26, causing voltage oscillation. The current sensing unit 26 has a smaller capacitance than the transistor portion 70, causing destructive failure of a trench of the current sensing unit 26 due to the oscillation. Therefore, it is preferable to suppress an influence of the holes sneaking into the current sensing unit 26.

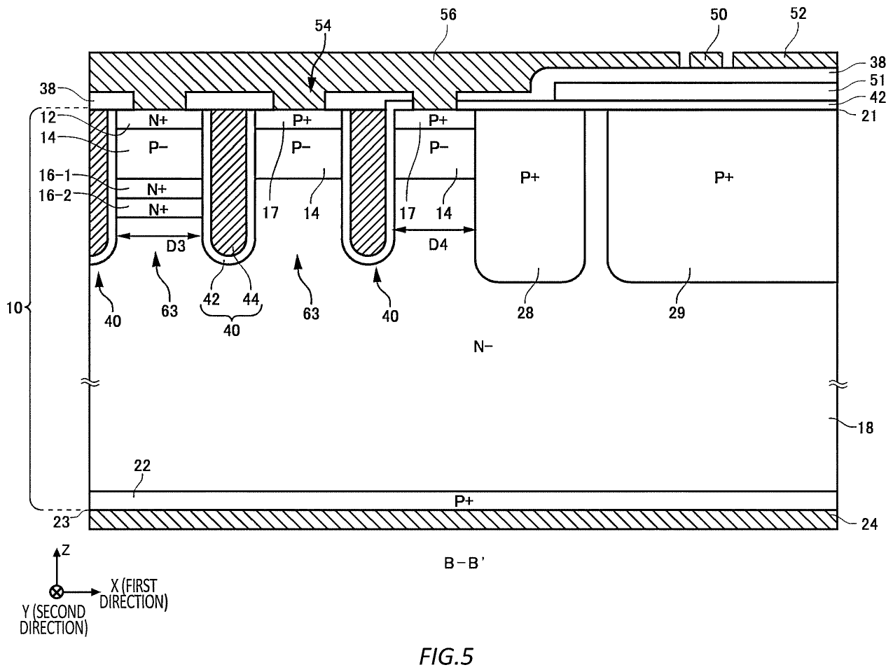

Providing the sense well region 28 can extract the holes which have sneaked into the current sensing unit 26, and can suppress accumulation of the holes in the current sensing unit 26. In the semiconductor device 100 in the present example, in the first direction, a width Wsu of the sense well region 28 is larger than a width Wt of the transistor portion 70 facing the current sensing unit 26. The width Wt of the transistor portion 70 may be a distance from one trench portion to another trench portion provided at boundaries between the transistor portion 70 and boundary regions 72 described later. This makes it possible to further extract the holes which have sneaked, and makes it difficult for the holes to be accumulated as carriers, and therefore the oscillation of the current sensing unit 26 can be suppressed. At this time, a P+ contact region 17 (see FIG. 5) may be provided on a surface side of a base region 14 in direct contact with the sense well region 28. For example, the P+ contact region 17 is provided in contact with an inner periphery of the sense well region 28 and so as to enclose the current sensing unit 26. This can make it easier to extract the holes which have flowed into the sense well region 28.

A width Ws of the current sensing unit 26 in the first direction may be smaller than the width Wt in the first direction of the transistor portion 70 facing the current sensing unit 26. This makes it possible to increase area of the sense well region 28 in a top view and to further extract the holes which have sneaked.

The sense well region 28 may be provided inside the active well region 29 in a top view. A potential of the current sensing unit 26 is different from that of the active well region 29 because there is a voltage drop across a sense resistor. Therefore, the sense well region 28 in the present example is separated from the active well region 29. It is sufficient that the active well region 29 and the sense well region 28 are separated by a distance large enough to withstand a potential difference caused by the voltage drop across the sense resistor. A distance D1 between the active well region 29 and the sense well region 28 may be 1 μm or more and 10 μm or smaller.

The sense well region 28 includes an inner peripheral end 34 facing the current sensing unit 26 in a top view, and an outer peripheral end 36 opposite to the inner peripheral end 34. A width Wu between the inner peripheral end 34 and the outer peripheral end 36 of the sense well region 28 may be larger than the distance D1 between the active well region 29 and the sense well region 28. This makes it possible to increase the area of the sense well region 28 in a top view and to further extract the holes which have sneaked.

At least part of the transistor portion 70 facing the current sensing unit 26 may be between pad portions 110. Being between the pad portions 110 means that the transistor portion 70 has a longitudinal part in the second direction up to a position at which it overlaps with the pad portions 110 in the first direction. In the present example, part of the transistor portion 70 is provided between the current control pad 114 and the auxiliary emitter pad 115. This makes it possible to increase area of the active portion 120. Accordingly, an inner peripheral end of the active well region 29 may also be provided between the pad portions 110. The transistor portion 70 may extend closer to the first end side 142 than the diode portion 80.

Two well regions, which are the active well region 29 and the sense well region 28, are provided between the transistor portion 70 and the current sensing unit 26. In addition, the current sensing unit 26 may be provided closer to the first end side 142 between the pad portions 110. If a region between the pad portions 110 is divided into two equal parts, which are a region on an active portion 120 side and a region on a first end side 142 side, area of the current sensing unit 26 provided in the region on the first end side 142 side may be larger than area of the current sensing unit 26 provided on the region on the active portion 120 side. This makes it possible to secure a region for the transistor portion 70 provided between the pad portions 110.

The semiconductor substrate 10 may include a boundary region 72 provided between the transistor portion 70 and the diode portion 80. The boundary region 72 in the present example is provided between the transistor portion 70 and the diode portion 80 in the first direction. The boundary region 72 may not include an emitter region on the upper surface of the semiconductor substrate 10, and may include a collector region on a lower surface of the semiconductor substrate 10. Providing the boundary region 72 can suppress sneaking holes from the transistor portion 70 into the diode portion 80 and suppress a switching loss in the diode portion 80.

An outer peripheral end portion position of the sense well region 28 in the first direction in the present example faces the boundary region 72 in the second direction. The holes sneaking into the current sensing unit 26 of the active portion 120 sneak only from the transistor portion 70, and do not sneak from the diode portion 80. Therefore, there is no need to provide the sense well region 28 extracting the holes which have sneaked, at a position where it faces the diode portion 80.

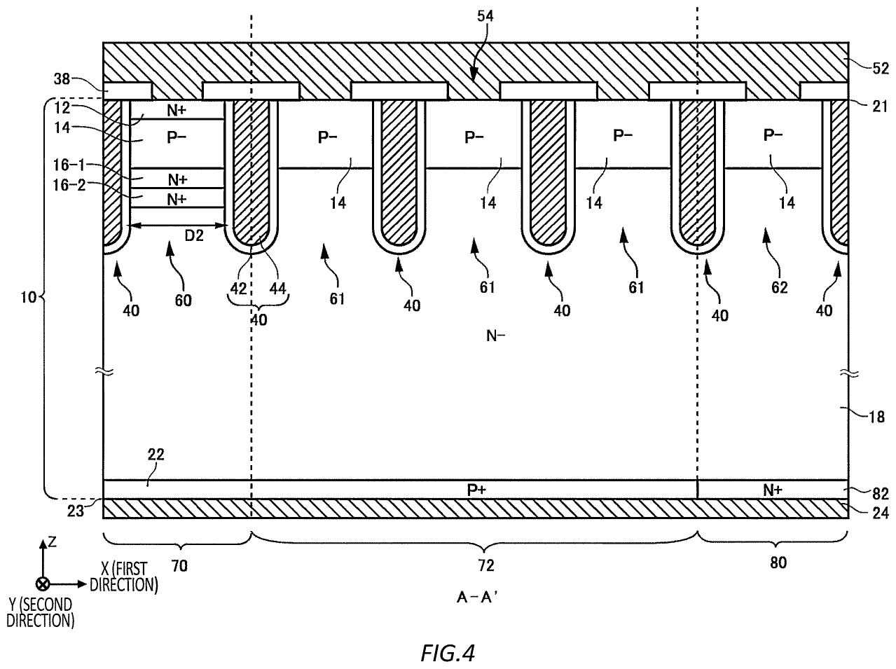

An inner peripheral end portion position of the sense well region 28 in the first direction may face the transistor portion 70 in the second direction. This makes it possible to increase the area of the sense well region 28 in a top view and to further extract the holes which have sneaked. FIG. 4 illustrates one example of a cross section A-A′ in FIG. 3. The cross section A-A′ is an XZ cross section passing through an emitter region 12 of the transistor portion 70, the boundary region 72, and the diode portion 80. In the cross section A-A′, the semiconductor device 100 includes the semiconductor substrate 10, a collector electrode 24, an interlayer dielectric film 38, and the emitter electrode 52. The semiconductor substrate 10 includes an upper surface 21 and a lower surface 23. The upper surface 21 and the lower surface 23 are two principal surfaces of the semiconductor substrate 10.

The interlayer dielectric film 38 is provided on the upper surface 21 of the semiconductor substrate 10. The interlayer dielectric film 38 is a film including at least one of a dielectric film such as silicate glass to which an impurity such as boron or phosphorus is added, a thermal oxide film, or another dielectric film. The interlayer dielectric film 38 is provided with a contact hole 54.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The emitter electrode 52 and the collector electrode 24 are formed of a metal material such as aluminum. In the present specification, the direction connecting the emitter electrode 52 and the collector electrode 24 (a Z axis direction) is referred to as the depth direction.

The transistor portion 70 and the diode portion 80 each include a drift region 18 of a first conductivity type, and the base region 14 of the second conductivity type provided between the drift region 18 and the upper surface 21 of the semiconductor substrate 10. Similarly, the boundary region 72 includes the drift region 18 of the first conductivity type, and the base region 14 of the second conductivity type provided between the drift region 18 and the upper surface 21 of the semiconductor substrate 10. The drift region 18 in the present example is of an N-type, and the base region 14 is of the P− type.

The transistor portion 70 includes a plurality of trench portions 40 provided from the upper surface 21 toward an inside of the semiconductor substrate 10. The trench portions 40 in the present example are arrayed along the first direction, and they each have a longitudinal part in the second direction. An interval between trench portions 40 of the transistor portion 70 in the first direction is referred to as D2. A trench portion 40 includes a trench, a gate dielectric film 42, and a gate conductive portion 44. The gate dielectric film 42 is provided covering an inner wall of the trench. The gate dielectric film 42 may be formed by oxidizing or nitriding a semiconductor on the inner wall of the trench. The gate conductive portion 44 is provided farther inward than the gate dielectric film 42 inside the trench. In other words, the gate dielectric film 42 insulates the gate conductive portion 44 from the semiconductor substrate 10. The gate conductive portion 44 is formed of a conductive material such as polysilicon. Similarly, the diode portion 80 and the boundary region 72 may each include a trench portion 40. A trench portion 40 may function as a gate trench or a dummy trench, or a plurality of trench portions 40 may have both functions.

Mesa portions 60 are provided between respective trench portions 40 of the transistor portion 70 in an array direction. A mesa portion 60 refers to a region between trench portions 40 inside the semiconductor substrate 10. For example, an upper end of the mesa portion 60 is the upper surface 21 of the semiconductor substrate 10. A depth position of a lower end of the mesa portion 60 is the same as a depth position of a lower end of the trench portion 40. The mesa portion 60 in the present example is provided extending in the second direction along the trench portion 40, on the upper surface 21 of the semiconductor substrate 10. Similarly, the boundary region 72 is provided with a mesa portion 61, and the diode portion 80 is provided with a mesa portion 62. If a term “mesa portion” is simply used in the present specification, it refers to each of the mesa portion 60, the mesa portion 61, and the mesa portion 62. Each mesa portion is provided with the base region 14.

The transistor portion 70 includes the emitter region 12 of the first conductivity type provided on the upper surface 21. The emitter region 12 is exposed on the upper surface 21 of the semiconductor substrate 10, and is provided in contact with the trench portion 40. The emitter region 12 may be in contact with trench portions 40 on both sides of the mesa portion 60. The emitter region 12 has a higher doping concentration than the drift region 18. The emitter region 12 in the present example is of the N+ type.

The base region 14 is provided below the emitter region 12. The base region 14 in the present example is provided in contact with the emitter region 12. The base region 14 may be in contact with the trench portions 40 on both sides of the mesa portion 60.

An accumulation region 16 is provided below the base region 14. The accumulation region 16 is a region of the N+ type having a higher doping concentration than the drift region 18. The semiconductor substrate 10 in the present example is provided with an accumulation region 16-1 and an accumulation region 16-2, but a number of at least one accumulation region 16 is not limited to this. Providing the accumulation region 16 with a high concentration between the drift region 18 and the base region 14 can increase a carrier injection enhancement effect (IE effect) and reduce an on-voltage. The accumulation region 16 may be provided so as to cover an entirety of a lower surface of the base region 14 in each mesa portion 60.

The mesa portion 62 of the diode portion 80 is provided with the base region 14 of the P− type, in contact with the upper surface 21 of the semiconductor substrate 10. The drift region 18 is provided below the base region 14. The diode portion 80 does not include the emitter region 12 on the upper surface 21 of the semiconductor substrate 10.

The semiconductor substrate 10 includes the boundary region 72 provided between the transistor portion 70 and the diode portion 80. The mesa portion 61 of the boundary region 72 is provided with the base region 14 of the P− type, in contact with the upper surface 21 of the semiconductor substrate 10. The drift region 18 is provided below the base region 14. The boundary region 72 does not include the emitter region 12 on the upper surface 21 of the semiconductor substrate 10.

The transistor portion 70 includes a collector region 22 of the second conductivity type provided on the lower surface 23 of the semiconductor substrate 10. The collector region 22 in the present example is of the P+ type. An acceptor concentration in the collector region 22 is higher than an acceptor concentration in the base region 14. The collector region 22 may include an acceptor which is the same as or different from an acceptor of the base region 14. The acceptor of the collector region 22 is, for example, boron. Similarly, the boundary region 72 includes the collector region 22 of the P+ type on the lower surface 23 of the semiconductor substrate 10.

The diode portion 80 includes a cathode region 82 of the first conductivity type provided on the lower surface 23 of the semiconductor substrate 10. The cathode region 82 in the present example is of the N+ type. A donor concentration in the cathode region 82 is higher than a donor concentration in the drift region 18. A donor in the cathode region 82 is, for example, hydrogen or phosphorus. It should be noted that an element serving as a donor and an acceptor in each region is not limited to the example described above. The collector region 22 and the cathode region 82 are exposed on the lower surface 23 of the semiconductor substrate 10, and are connected to the collector electrode 24. The collector electrode 24 may be in contact with an entirety of the lower surface 23 of the semiconductor substrate 10. The emitter electrode 52 and the collector electrode 24 are formed of a metal material such as aluminum.

In a cross section different from the cross section A-A′, the transistor portion 70, the boundary region 72, and the diode portion 80 may each be provided with a contact region of the second conductivity type. The contact region may be provided between the base region 14 and the upper surface 21. The contact region may be a region of the P+ type having a higher doping concentration than the base region 14.

The boundary between the transistor portion 70 and the boundary region 72 may have the collector region 22 on the lower surface 23, and may be a center of a trench portion 40 located between the mesa portion 60 provided with the emitter region 12 and the mesa portion 61 not provided with the emitter region 12. A boundary between the boundary region 72 and the diode portion 80 may be a boundary between the cathode region 82 and the collector region 22.

Each trench portion 40 extends from the upper surface 21 of the semiconductor substrate 10 through the base region 14, to reach the drift region 18. In a region provided with at least any of the emitter region 12, the contact region, or the accumulation region 16, each trench portion 40 also extends through these doping regions, to reach the drift region 18. A configuration of the trench portions 40 extending through the doping regions is not limited to what is manufactured in an order of forming the doping regions and then forming the trench portions 40. The configuration of the trench portions 40 extending through the doping regions also includes a configuration of forming the trench portions 40 and then forming the doping regions between the trench portions 40. It should be noted that a bottom portion of the gate trench portion 40 may have a curved-surface shape (a curved-line shape in the cross section) protruding downward.

The gate conductive portion 44 may be provided longer than the base region 14 in the depth direction. The trench portion 40 in the cross section is covered by the interlayer dielectric film 38 on the upper surface 21 of the semiconductor substrate 10. At least one gate conductive portion 44 in the transistor portion 70 among gate conductive portions 44 of the plurality of trench portions 40 is electrically connected to a gate wiring. When a predetermined gate voltage is applied to the gate conductive portion 44, a channel is formed by an electron inversion layer in a surface layer of the base region 14 at a boundary surface in contact with the gate trench portion 40. As a result, in the transistor portion 70, a main current flows between the emitter electrode 52 and the collector electrode 24.

FIG. 5 illustrates one example of a cross section B-B′ in FIG. 3. The cross section B-B′ is an XZ cross section passing through the emitter region 12 of the current sensing unit 26, the sense well region 28, and the active well region 29. In the cross section B-B′, the semiconductor device 100 includes the semiconductor substrate 10, the collector electrode 24, the interlayer dielectric film 38, the gate dielectric film 42, a gate runner for current sensing 51, the emitter electrode 52, a sense emitter electrode 56, and a first gate runner 50.

The interlayer dielectric film 38 is provided on the upper surface 21 of the semiconductor substrate 10. The emitter electrode 52, the sense emitter electrode 56, and the first gate runner 50 are provided above the interlayer dielectric film 38. The sense emitter electrode 56 is in contact with the upper surface 21 of the semiconductor substrate 10 through the contact hole 54 of the interlayer dielectric film 38. The sense emitter electrode 56 is formed of a metal material such as aluminum. The collector electrode 24 is provided on a lower surface 23 of the semiconductor substrate 10.

On the upper surface 21 of the semiconductor substrate 10, the sense emitter electrode 56 and the emitter electrode 52 are separated from each other. The sense emitter electrode 56 is connected to the emitter electrode 52 via a sense resistor. The first gate runner 50 is provided between the sense emitter electrode 56 and the emitter electrode 52.

In the depth direction, the gate runner for current sensing 51 is provided between the sense emitter electrode 56, the first gate runner 50, and the emitter electrode 52, and the upper surface 21 of the semiconductor substrate 10. The gate runner for current sensing 51 is electrically insulated from the semiconductor substrate 10 by the gate dielectric film 42 provided extending on the upper surface 21 of the semiconductor substrate 10. In the cross section B-B′, the gate runner for current sensing 51 is insulated from the sense emitter electrode 56, the first gate runner 50, and the emitter electrode 52 by the interlayer dielectric film 38. In another cross section, the gate runner for current sensing 51 may be connected to the first gate runner 50. In another cross section, the gate runner for current sensing 51 may be connected to the gate conductive portion 44 of the current sensing unit 26. The first gate runner 50 and the gate runner for current sensing 51 may apply a gate voltage to the gate conductive portion 44 of the current sensing unit 26.

The sense emitter electrode 56 is electrically connected to the sense well region 28 via the contact hole 54 provided in the interlayer dielectric film 38 and the P+ contact region 17 or the base region 14. The first gate runner 50 is electrically insulated from the active well region 29 by the interlayer dielectric film 38. The sense well region 28 and the active well region 29 are regions of the P+ type in contact with the upper surface 21 of the semiconductor substrate 10. In the depth direction, the sense well region 28 and the active well region 29 may be provided to a depth greater than that of the base region 14, and may be provided to a depth greater than that of the trench portion 40.

The current sensing unit 26 includes the drift region 18 of the first conductivity type, and the base region 14 of the second conductivity type provided between the drift region 18 and the upper surface 21 of the semiconductor substrate 10. The current sensing unit 26 includes a plurality of trench portions 40 provided from the upper surface 21 toward the inside of the semiconductor substrate 10. The trench portions 40 in the present example are arrayed along the first direction, and they each have a longitudinal part in the second direction.

The current sensing unit 26 includes a mesa portion 63 which is a region between trench portions 40. In the present example, the mesa portion 63 is provided between the trench portions 40 in the first direction, and extends in the second direction. Similarly to the transistor portion 70, the mesa portion 63 is provided with the emitter region 12, the base region 14, and the accumulation region 16 from the upper surface 21. The current sensing unit 26 includes the collector region 22 of the P+ type on the lower surface 23. A function of each component and a configuration of the current sensing unit 26 may be similar to those of the transistor portion 70.

The emitter region 12 and the accumulation region 16 may not be provided in the mesa portion 63 provided at a very end of the current sensing unit 26 in the first direction. The emitter region 12 and the accumulation region 16 may not be provided in a region between the trench portion 40 provided at the very end of the current sensing unit 26 in the first direction and the sense well region 28, either.

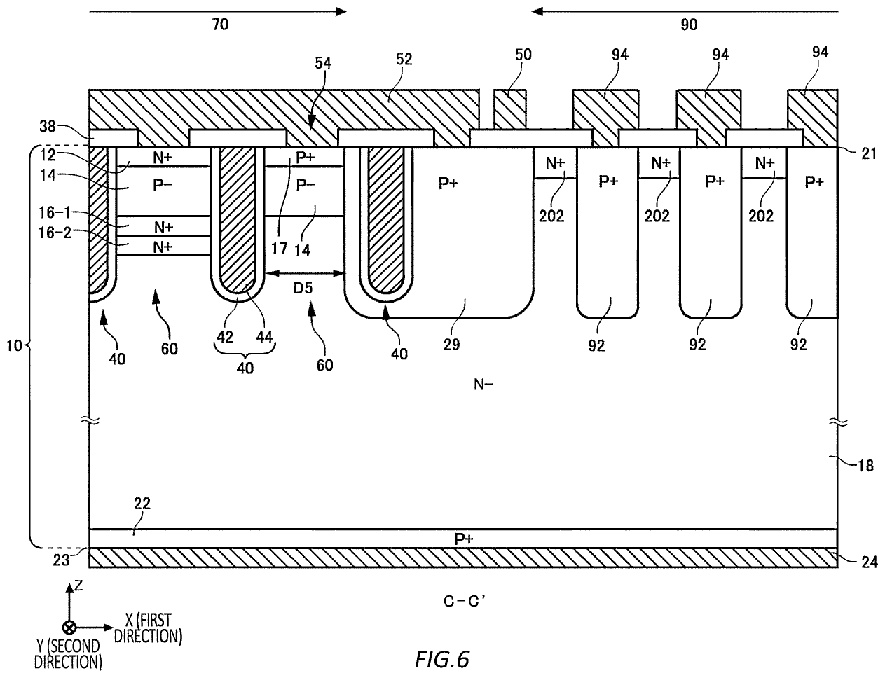

A distance in the first direction between the trench portion 40 provided at the very end of the current sensing unit 26 in the first direction and the sense well region 28 is referred to as D4. The distance D4 may be smaller than a distance D5 (see FIG. 6) in the first direction between the trench portion 40 provided at a very end of the transistor portion 70 in the first direction and the active well region 29. This decreases a distance between the current sensing unit 26 and the sense well region 28, making it possible to extract more holes, which have sneaked from the transistor portion 70, via the sense well region 28 and to suppress accumulation of carriers. At this time, the P+ contact region 17 may be provided on the surface side of the base region 14 in direct contact with the sense well region 28. For example, the P+ contact region 17 is provided in contact with the inner periphery of the sense well region 28 and so as to enclose the current sensing unit 26. This can make it easier to extract the holes which have flowed into the sense well region 28.

In a cross section different from the cross section B-B′, the current sensing unit 26 may be provided with a contact region of the second conductivity type. The contact region may be provided between the base region 14 and the upper surface 21. The contact region may be a region of the P+ type having a higher doping concentration than the base region 14. Providing the contact region in the current sensing unit 26 can extract the holes, which have sneaked from the transistor portion 70, via the contact region.

An interval between trench portions 40 of the current sensing unit 26 in the first direction is referred to as D3. The interval D3 may be larger than the interval D2 (see FIG. 4) between the trench portions 40 of the transistor portion 70 in the first direction. This increases area of the contact region of the current sensing unit 26, making it possible to extract more holes.

FIG. 6 illustrates one example of a cross section C-C′ in FIG. 2. The cross section C-C′ is an XZ cross section passing through the emitter region 12 of the transistor portion 70, the active well region 29, and part of the edge termination structure portion 90. In the cross section C-C′, the semiconductor device 100 includes the semiconductor substrate 10, the collector electrode 24, the interlayer dielectric film 38, the emitter electrode 52, the first gate runner 50, and a field plate 94. The transistor portion 70 may have a same configuration as that of the transistor portion 70 described with reference to FIG. 4.

In the semiconductor substrate 10, the active well region 29 is provided between the edge termination structure portion 90 and the transistor portion 70. The active well region 29 is a region of the P+ type in contact with the upper surface 21 of the semiconductor substrate 10. Some of the trench portions 40 may be arranged at a position where it overlaps with the active well region 29.

The upper surface 21 of the semiconductor substrate 10 may be provided with the interlayer dielectric film 38 covering the active well region 29. An electrode and a wiring such as the emitter electrode 52 and the first gate runner 50 are provided above the interlayer dielectric film 38. The emitter electrode 52 is provided extending from above the active portion 120 to above the active well region 29. The emitter electrode 52 may be connected to the active well region 29 via the contact hole 54 provided in the interlayer dielectric film 38.

The first gate runner 50 is arranged between the emitter electrode 52 and the edge termination structure portion 90. The emitter electrode 52 and the first gate runner 50 are arranged separately from each other. The first gate runner 50 is electrically insulated from the active well region 29 by the interlayer dielectric film 38.

The edge termination structure portion 90 is provided with a plurality of guard rings 92, a plurality of high concentration regions 202, and a plurality of field plates 94. A guard ring 92 in the present example is a semiconductor region of the P+ type formed near the upper surface 21 through ion implantation. The guard ring 92 can be formed by selectively implanting a P type dopant such as boron from the upper surface 21 of the semiconductor substrate 10 and performing heat treatment. A depth of a bottom portion of the guard ring 92 may be the same as or different from a depth of a bottom portion of the active well region 29.

An upper surface of the guard ring 92 is covered with the interlayer dielectric film 38. The field plate 94 is formed of a metal such as aluminum or a conductive material such as polysilicon. The field plate 94 may be formed of an aluminum-silicon alloy, for example, a metal alloy such as AlSi or AlSiCu. The field plate 94 may be formed of a same material as that of the first gate runner 50 or the emitter electrode 52. The field plate 94 is provided on the interlayer dielectric film 38. The field plate 94 in the present example is connected to the guard ring 92 through the contact hole 54 provided in the interlayer dielectric film 38.

In the edge termination structure portion 90, the collector region 22 may be provided in a region in contact with the lower surface 23. Each guard ring 92 may be provided so as to enclose the active portion 120 on the upper surface 21. The plurality of guard rings 92 may have a function of expanding a depletion layer generated in the active portion 120, toward an outside of the semiconductor substrate 10. This makes it possible to prevent electric field strength inside the semiconductor substrate 10 and to improve a breakdown voltage of the semiconductor device 100.

The distance in the first direction between the trench portion 40 provided at the very end of the transistor portion 70 in the first direction and the active well region 29 is referred to as D5. The emitter region 12 and the accumulation region 16 may not be provided between the trench portion 40 provided at the very end of the transistor portion 70 in the first direction and the active well region 29. The P+ contact region 17 may be provided on the surface side of the base region 14 between the trench portion 40 provided at the very end of the transistor portion 70 in the first direction and the active well region 29.

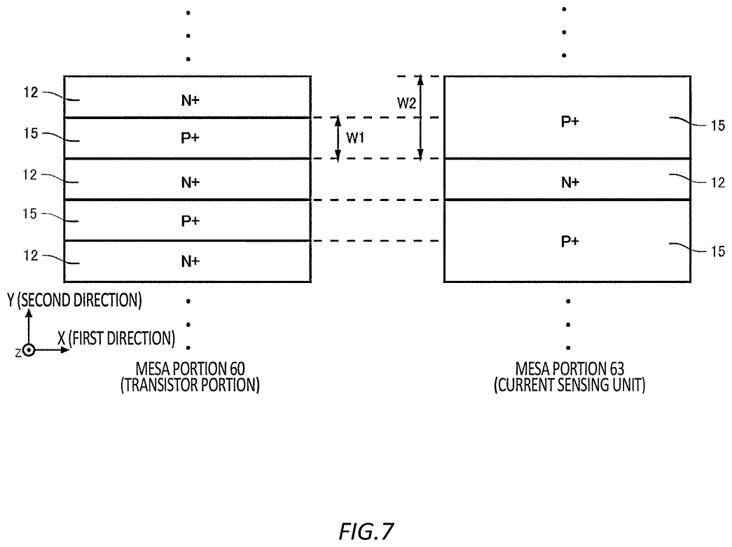

FIG. 7 illustrates top views of the mesa portion 60 of the transistor portion 70 and the mesa portion 63 of the current sensing unit 26. For comparison, FIG. 7 shows respective mesa portions side by side. The transistor portion 70 and the current sensing unit 26 each include the emitter region 12 and a contact region 15. The contact region 15 is provided between the base region 14 and the upper surface 21 of the semiconductor substrate 10, and is a region of the second conductivity type having a higher concentration than the base region 14.

A ratio of area of the contact region 15 to area of one mesa portion 63 of the current sensing unit 26 may be greater than a ratio of area of the contact region 15 to area of one mesa portion 60 of the transistor portion 70. This allows the ratio of the area of the contact region 15 for the current sensing unit 26 to be higher than the ratio of the area of the contact region 15 for the transistor portion 70, making it possible to extract more holes via the contact region 15 of the current sensing unit 26.

In the present example, the emitter region 12 and the contact region 15 are alternately arranged along the second direction (the Y axis direction). A length W2 of the contact region 15 of the current sensing unit 26 in the second direction may be larger than a length W1 of the contact region 15 of the transistor portion 70 in the second direction. This allows the ratio of the area of the contact region 15 for the current sensing unit 26 to be higher than the ratio of the area of the contact region 15 for the transistor portion 70, making it possible to extract more holes via the contact region 15 of the current sensing unit 26.

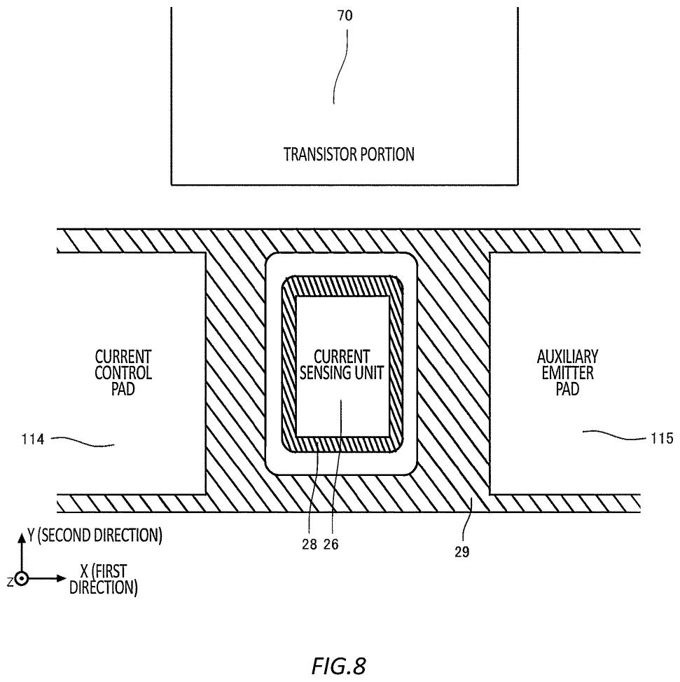

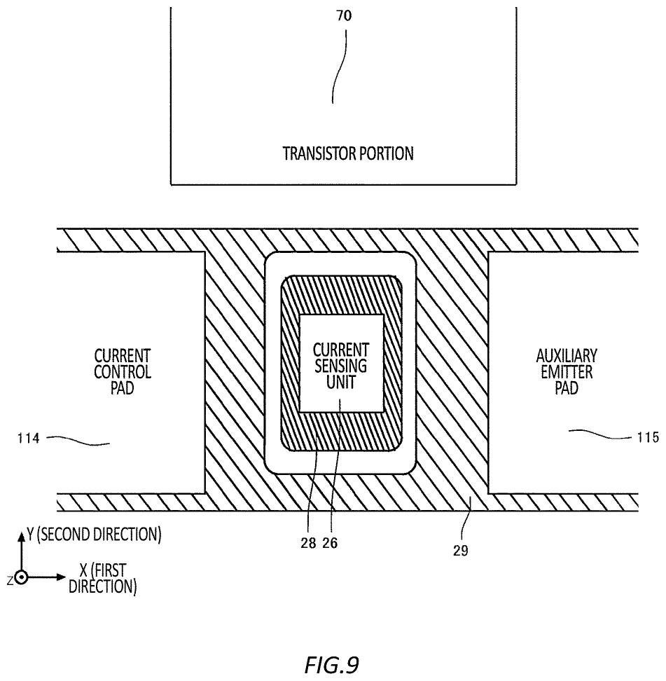

FIG. 8 illustrates arrangement around the current sensing unit 26 of a measurement sample with a large chip size. FIG. 9 illustrates arrangement around the current sensing unit 26 of a measurement sample with a small chip size. The inventors measured the samples shown in FIG. 8 and FIG. 9 in order to examine dependency of a short circuit withstand time on active area. The large chip size means that area of the active portion 120 is large. An area ratio between the area of the active portion 120 and area of the current sensing unit 26 is set to a predetermined ratio regardless of a chip size. In addition, combined area of the current sensing unit 26 and the sense well region 28 is constant regardless of the chip size. Therefore, if the chip size is large, the area of the current sensing unit 26 accordingly becomes also large. Accordingly, a distance in the second direction between the transistor portion 70 and the current sensing unit 26 becomes small. On the other hand, if the chip size is small, the area of the current sensing unit 26 also accordingly becomes small. Accordingly, the distance in the second direction between the transistor portion 70 and the current sensing unit 26 becomes large.

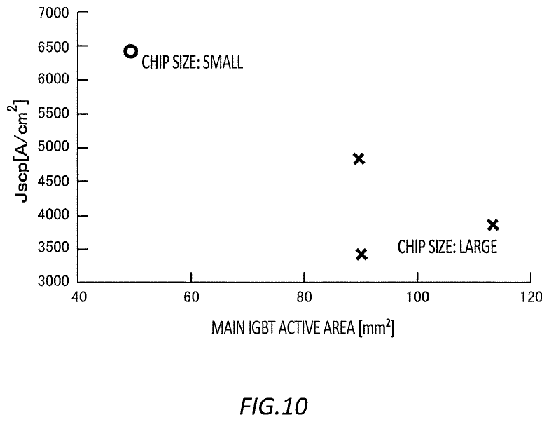

FIG. 10 illustrates a result of measurement of the dependency of the short circuit withstand time on the active area. A horizontal axis and a vertical axis in FIG. 10 respectively represent area of the transistor portion 70 and a current density in the current sensing unit 26. There is a tendency that the smaller the chip size is, in other words, the larger the distance between the transistor portion 70 and the current sensing unit 26 is, the longer the withstand time is. This is believed to be because the larger the distance between the transistor portion 70 and the current sensing unit 26 is, the less sneaking holes from the transistor portion 70 into the current sensing unit 26 there are.

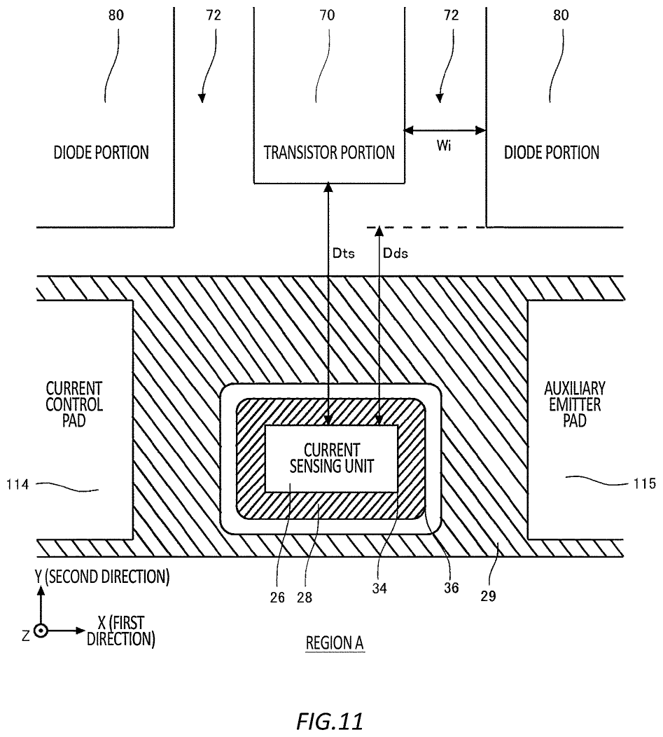

FIG. 11 illustrates another example of the region A in FIG. 2. The transistor portion 70 may not be provided between pad portions 110. A distance Dts in the second direction between the transistor portion 70 facing the current sensing unit 26 and the current sensing unit 26 may be larger than a distance Dds in the second direction between the diode portion 80 and the current sensing unit 26. This makes it possible to secure the distance between the transistor portion 70 and the current sensing unit 26 and to suppress sneaking holes from the transistor portion 70 into the current sensing unit 26. The distance Dts in the second direction between the transistor portion 70 and the current sensing unit 26 may be 500 μm or more.

If holes sneak from the transistor portion 70 into the diode portion 80, the switching loss increases, but some sneaking is tolerated. On the other hand, holes sneaking from the transistor portion 70 into the current sensing unit 26 will lead to destructive failure of the current sensing unit 26 due to oscillation. Therefore, the distance Dts in the second direction between the transistor portion 70 facing the current sensing unit 26 and the current sensing unit 26 may be larger than a width Wi of the boundary region 72 in the first direction. This makes it possible to more reliably suppress the sneaking holes from the transistor portion 70 into the current sensing unit 26 than the sneaking holes from the transistor portion 70 into the diode portion 80. It should be noted that a relationship between the distance and the width described above may also hold for FIG. 3.

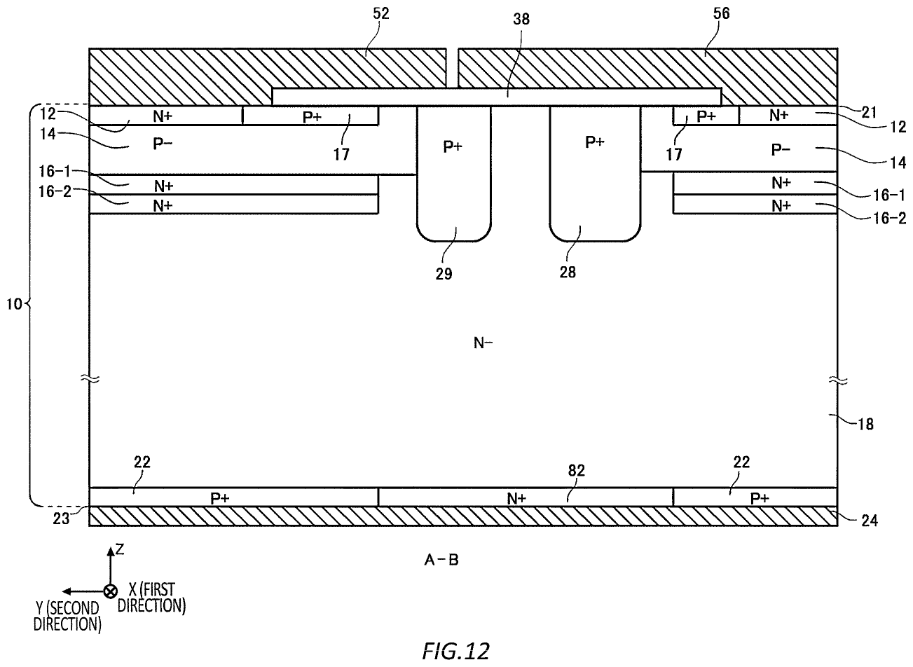

FIG. 12 illustrates one example of a cross section A-B in FIG. 3. The cross section A-B is a YZ cross section passing through the transistor portion 70 and the current sensing unit 26. Configurations of the transistor portion 70 and the current sensing unit 26 may be the same as any of the configurations described with reference to FIG. 1 to FIG. 11.

In the second direction, a region of the first conductivity type may be provided on the lower surface 23 of the semiconductor substrate 10 between the transistor portion 70 and the current sensing unit 26. The cathode region 82 of the N+ type is provided on the lower surface 23 of the semiconductor substrate 10 between the transistor portion 70 and the current sensing unit 26 in the present example. This makes it possible to suppress the sneaking holes from the transistor portion 70 into the current sensing unit 26.

In the cross section A-B, upper surfaces of the active well region 29 and the sense well region 28 are covered with the interlayer dielectric film 38. In the cross section A-B, the P+ contact region 17 may be provided in an end portion of the transistor portion 70 in contact with the active well region 29. In addition, the P+ contact region 17 may be provided in an end portion of the current sensing unit 26 in contact with the sense well region 28. The interlayer dielectric film 38 may cover part of the P+ contact region 17.

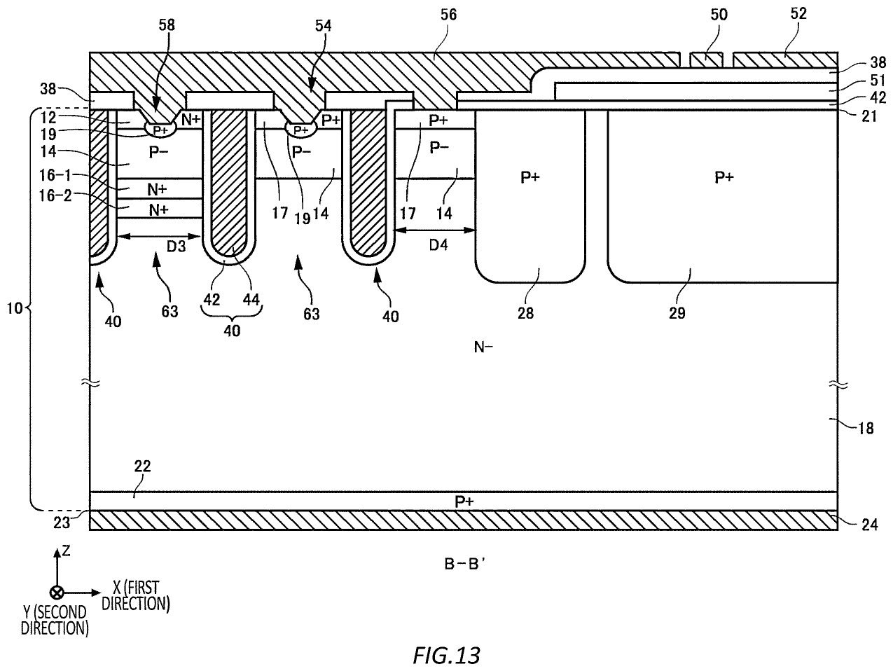

FIG. 13 illustrates another example of the cross section B-B′ in FIG. 3. At least one mesa portion 63 of the current sensing unit 26 in the present example is provided with: the emitter region 12 of the first conductivity type or the P+ contact region 17 of the second conductivity type provided between the drift region 18 and the upper surface 21 of the semiconductor substrate 10; the base region 14 of the second conductivity type provided between the drift region 18 and the upper surface 21 of the semiconductor substrate 10; and a trench contact 58 provided from the upper surface 21 toward the inside of the semiconductor substrate 10, and a bottom portion P region 19 provided in a bottom portion of the trench contact 58 in the depth direction. Providing the trench contact 58 and the bottom portion P region 19 can extract holes which have sneaked, and can suppress accumulation of carriers. The trench contact 58 may or may not extend through the emitter region 12 or the P+ contact region 17. The bottom portion P region 19 may be in contact with the base region 14. The trench contact 58 and the bottom portion P region 19 may also be provided in the mesa portion 63 provided at the very end of the current sensing unit 26 in the first direction and not provided with the emitter region 12 and the accumulation region 16. Except for the mesa portion 63, a configuration in FIG. 13 may be similar to that in FIG. 5. The mesa portion 60 of the transistor portion 70 may not include the trench contact 58 and the bottom portion P region 19.

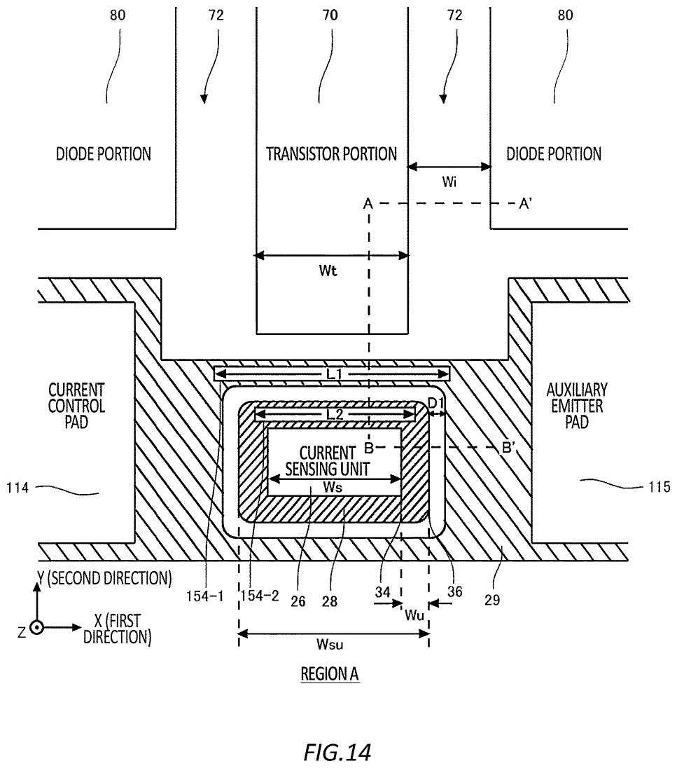

FIG. 14 illustrates another example of an enlarged view of the region A in FIG. 2. The region A in the present example is different from the region A shown in FIG. 2 in that a contact hole 154 is provided in a top view. Except for that, a configuration in this figure is similar to that in FIG. 2, and therefore description thereof will be omitted.

The contact hole 154 may be provided between the transistor portion 70 and the current sensing unit 26 in the second direction. In the present example, a contact hole 154-1 and a contact hole 154-2 are provided. The contact hole 154-1 connects the active well region 29 to an electrode. The contact hole 154-2 connects the sense well region 28 to an electrode.

Only one of the contact hole 154-1 or the contact hole 154-2 may be provided, or both the contact hole 154-1 and the contact hole 154-2 may be provided. A plurality of contact holes 154-1 may be provided in the X axis direction.

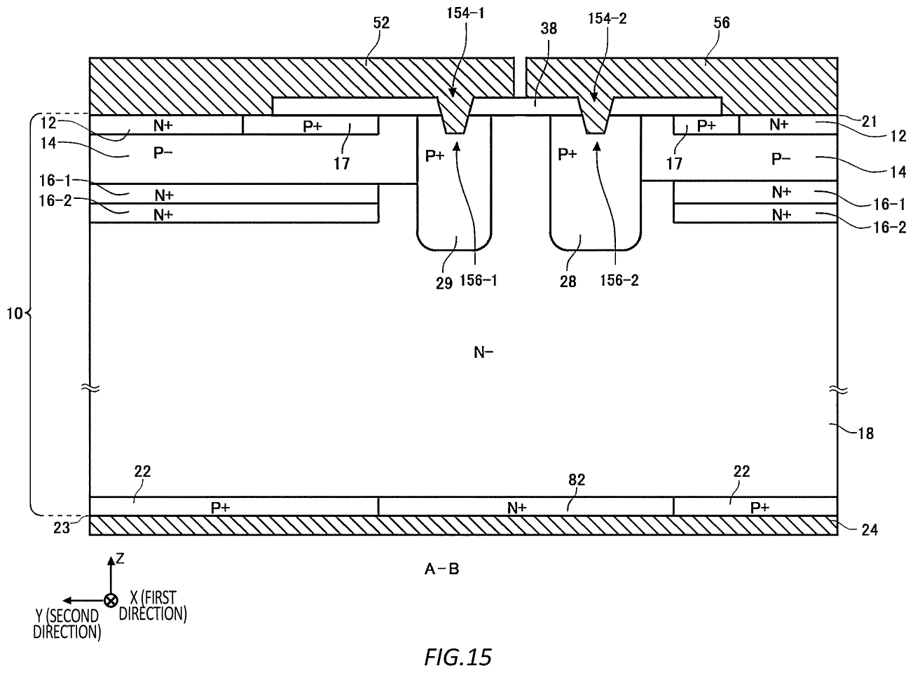

FIG. 15 illustrates the cross section A-B in FIG. 14. The cross section A-B in the present example is different from the cross section A-B shown in FIG. 12 in that the contact hole 154 and a trench contact for extraction 156 are provided and that a boundary between the emitter electrode 52 and the sense emitter electrode 56 is located on a negative side in the Y axis direction. Except for that, a configuration in this figure is similar to that in FIG. 12, and therefore description thereof will be appropriately omitted.

The semiconductor device 100 in the present example also includes the interlayer dielectric film 38 provided on the upper surface 21 of the semiconductor substrate 10. The sense emitter electrode 56 is provided above the interlayer dielectric film 38. The interlayer dielectric film 38 includes the contact hole 154-2 between the transistor portion 70 and the current sensing unit 26 in the second direction. The contact hole 154-2 in the present example is provided above the sense well region 28.

The sense emitter electrode 56 and the sense well region 28 are connected to each other via the contact hole 154-2. This makes it possible to further extract the holes which have sneaked into the current sensing unit 26.

An upper surface electrode may be provided above the interlayer dielectric film 38. The upper surface electrode may be the emitter electrode 52 provided above the transistor portion 70, or may be the sense emitter electrode 56. The semiconductor device 100 may include a well region of the second conductivity type provided between the transistor portion 70 and the sense well region 28 in the second direction. The well region may be the active well region 29 enclosing the transistor portion 70 and the diode portion 80 in a top view, may be the active well region 29 not enclosing the transistor portion 70 and the diode portion 80, or may be another region of the second conductivity type.

The interlayer dielectric film 38 may include the contact hole 154-1 between the transistor portion 70 and the sense well region 28 in the second direction. The upper surface electrode and the well region may be connected to each other via the contact hole 154-1. This also makes it possible to further extract the holes which have sneaked into the current sensing unit 26.

In the present example, the emitter electrode 52 and the active well region 29 are connected to each other via the contact hole 154-1. In another example, the emitter electrode 52, and the active well region 29 not enclosing the transistor portion 70 and the diode portion 80 may be connected to each other, or the sense emitter electrode 56 and another region of the second conductivity type may be connected to each other via the contact hole 154-1. A position of the contact hole 154-1 in the second direction may be appropriately adjusted within a range from the transistor portion 70 to the sense well region 28 depending on the upper surface electrode to be connected.

Lower ends of the contact hole 154-1 and the contact hole 154-2 are respectively provided with a trench contact for extraction 156-1 and a trench contact for extraction 156-2 formed from the upper surface 21 toward the inside of the semiconductor substrate 10. This further improves an effect of extracting the holes. A depth of the trench contact for extraction 156 may be the same as or different from a depth of a trench contact provided in the active portion 120. The depth of the trench contact for extraction 156 may be the same as or different from a depth of the trench contact 58 (see FIG. 13) provided in the current sensing unit 26. A width of the trench contact for extraction 156 may be larger than or the same as a width of the trench contact provided in the active portion 120. The width of the trench contact for extraction 156 may be larger than or the same as a width of the trench contact 58 provided in the current sensing unit 26.

A length of the contact hole 154-1 in the first direction is referred to as L1 (see FIG. 14). In addition, a length of the contact hole 154-2 in the first direction is referred to as L2 (see FIG. 14). The length L1 and the length L2 may be larger than at least one of the width Wt of the transistor portion 70 facing the current sensing unit 26 or the width Ws of the current sensing unit 26. This makes it possible to extract the holes which have sneaked from the transistor portion 70, before they reach the current sensing unit 26. The length L1 and the length L2 may be larger than both the width Wt of the transistor portion 70 facing the current sensing unit 26 and the width Ws of the current sensing unit 26. In addition, the length L1 may be larger than the length L2.

The contact hole 154-1 may be provided so as to enclose the current sensing unit 26. Similarly, the contact hole 154-2 may also be provided so as to enclose the current sensing unit 26. This makes it possible to further extract the holes which have sneaked into the current sensing unit 26. The contact hole 154-1 and the contact hole 154-2 may be provided in discrete dots.

While the present invention has been described by way of the embodiments, the technical scope of the present invention is not limited to the above-described embodiments. It is apparent to persons skilled in the art that various alterations or improvements can be made to the above described embodiments. It is also apparent from the description of the claims that embodiments added with such alterations or improvements can be included in the technical scope of the present invention.

What is claimed is:

1. A semiconductor device comprising a semiconductor substrate, wherein
the semiconductor substrate has:
a transistor portion and a diode portion alternately arranged along a first direction, each having a longitudinal part in a second direction; and
a current sensing unit arranged facing the transistor portion in the second direction,
the transistor portion, the diode portion, and the current sensing unit each include:
a drift region of a first conductivity type; and
a base region of a second conductivity type provided between the drift region and an upper surface of the semiconductor substrate,
in a top view, the current sensing unit is enclosed by a sense well region of the second conductivity type, the sense well region having a higher concentration than the base region and being provided to a depth greater than that of the base region from the upper surface, and
in the second direction, a width, in the first direction, of the sense well region is larger than a width, in the first direction, of the transistor portion facing the current sensing unit.

2. The semiconductor device according to claim 1, wherein
the semiconductor substrate has an active well region enclosing the transistor portion and the diode portion in a top view, and
the sense well region is provided inside the active well region in a top view.

3. The semiconductor device according to claim 2, wherein
a plurality of pad portions are provided above the active well region, and
the current sensing unit is arranged between two pad portions of the pad portions in the first direction.

4. The semiconductor device according to claim 3, wherein
at least part of the transistor portion facing the current sensing unit is between the two pad portions.

5. The semiconductor device according to claim 1, wherein
the transistor portion includes:
an emitter region of the first conductivity type provided on the upper surface; and
a collector region of the second conductivity type provided on a lower surface of the semiconductor substrate,
the diode portion
does not include the emitter region on the upper surface, and
includes a cathode region of the first conductivity type provided on the lower surface,
the semiconductor substrate further includes
a boundary region: provided between the transistor portion and the diode portion; not including the emitter region on the upper surface; and including the collector region on the lower surface, and
an outer peripheral end portion position of the sense well region in the first direction faces the boundary region in the second direction.

6. The semiconductor device according to claim 2, wherein
the transistor portion and the current sensing unit each include a plurality of trench portions: arrayed along the first direction; each having a longitudinal part in the second direction; and provided from the upper surface toward an inside of the semiconductor substrate, and
a distance in the first direction between a trench portion of the trench portions which is provided at a very end of the current sensing unit in the first direction and the sense well region is smaller than a distance in the first direction between a trench portion of the trench portions which is provided at a very end of the transistor portion in the first direction and the active well region.

7. The semiconductor device according to claim 2, wherein
the sense well region includes an inner peripheral end facing the current sensing unit in a top view, and an outer peripheral end opposite to the inner peripheral end, and
a width between the inner peripheral end of the sense well region and the outer peripheral end is larger than a distance between the active well region and the sense well region.

8. The semiconductor device according to claim 1, wherein
the transistor portion and the current sensing unit each include:
a plurality of trench portions provided from the upper surface toward an inside of the semiconductor substrate;
a mesa portion which is a region between the trench portions; and
a contact region of the second conductivity type provided between the base region and the upper surface of the semiconductor substrate and having a higher concentration than the base region, and
a ratio of area of the contact region to area of one mesa portion, which is the mesa portion, of the current sensing unit is greater than a ratio of area of the contact region to area of one mesa portion, which is the mesa portion, of the transistor portion.

9. The semiconductor device according to claim 8, wherein
a length of the contact region of the current sensing unit in the second direction is larger than a length of the contact region of the transistor portion in the second direction.

10. The semiconductor device according to claim 1, wherein
the transistor portion and the current sensing unit each include a plurality of trench portions: arrayed along the first direction; each having a longitudinal part in the second direction; and provided from the upper surface toward an inside of the semiconductor substrate, and
an interval between the trench portions of the current sensing unit in the first direction is larger than an interval between the trench portions of the transistor portion in the first direction.

11. The semiconductor device according to claim 1, wherein
a distance in the second direction between the transistor portion facing the current sensing unit and the current sensing unit is larger than a distance in the second direction between the diode portion and the current sensing unit.

12. The semiconductor device according to claim 1, wherein
the semiconductor substrate includes
a boundary region provided between the transistor portion and the diode portion, and
a distance in the second direction between the transistor portion facing the current sensing unit and the current sensing unit is larger than a width of the boundary region in the first direction.

13. The semiconductor device according to claim 1, wherein
in the second direction, a region of the first conductivity type is provided on a lower surface of the semiconductor substrate between the transistor portion and the current sensing unit.

14. The semiconductor device according to claim 1, wherein
a distance in the second direction between the transistor portion and the current sensing unit is 500 μm or more.

15. The semiconductor device according to claim 1, wherein
the current sensing unit includes:
a plurality of trench portions provided from the upper surface toward an inside of the semiconductor substrate; and
a mesa portion which is a region between the trench portions, and
at least one mesa portion including the mesa portion is provided with:
an emitter region of the first conductivity type provided between the drift region and the upper surface of the semiconductor substrate;
the base region; and
a trench contact provided from the upper surface toward the inside of the semiconductor substrate.

16. The semiconductor device according to claim 15, wherein
the transistor portion includes:
a plurality of trench portions provided from the upper surface toward the inside of the semiconductor substrate; and
a mesa portion which is a region between the trench portions, and
the mesa portion of the transistor portion does not include a trench contact provided from the upper surface toward the inside of the semiconductor substrate.

17. The semiconductor device according to claim 1, wherein
a width of the current sensing unit in the first direction is smaller than the width in the first direction of the transistor portion facing the current sensing unit.

18. The semiconductor device according to claim 1, wherein
an inner peripheral end portion position of the sense well region in the first direction faces the transistor portion in the second direction.

19. The semiconductor device according to claim 1, further comprising:
an interlayer dielectric film provided on the upper surface of the semiconductor substrate; and
a sense emitter electrode provided above the interlayer dielectric film, wherein
the interlayer dielectric film includes a contact hole between the transistor portion and the current sensing unit in the second direction, and
the sense emitter electrode and the sense well region are connected via the contact hole.

20. The semiconductor device according to claim 1, further comprising:
an interlayer dielectric film provided on the upper surface of the semiconductor substrate;
an upper surface electrode provided above the interlayer dielectric film; and
a well region of the second conductivity type provided between the transistor portion and the sense well region in the second direction, wherein
the interlayer dielectric film includes a contact hole between the transistor portion and the sense well region in the second direction, and
the upper surface electrode and the well region are connected via the contact hole.

21. The semiconductor device according to claim 20, wherein
the well region is an active well region enclosing the transistor portion and the diode portion in a top view, and
the upper surface electrode is an emitter electrode provided above the transistor portion.

22. The semiconductor device according to claim 19, wherein
in the first direction, a length of the contact hole is larger than at least one of the width of the transistor portion facing the current sensing unit or a width of the current sensing unit.

23. The semiconductor device according to claim 19, wherein
a lower end of the contact hole is provided with a trench contact for extraction formed from the upper surface toward an inside of the semiconductor substrate.

24. The semiconductor device according to claim 1, wherein
the current sensing unit further includes an emitter region of the first conductivity type provided between the base region and the upper surface of the semiconductor substrate and having a higher doping concentration than the drift region.
